(19) United States
(12) Patent Application Publication
(10) Pub. No.: US 2026/0082157 A1
(43) Pub. Date: Mar. 19, 2026

(54) MEMS MICROPHONE AND METHOD FOR PREPARING MEMS MICROPHONE

(71) Applicant: AAC ACOUSTIC TECHNOLOGIES (SHENZHEN) CO., LTD., Shenzhen (CN)

(72) Inventors: Yu Chen, Singapore (SG); Tze Xuan Fong, Bandar Seri Begawan (BN); Rong Ong, Singapore (SG); Yu Sheng Cheng, Singapore (SG); Chun Pheng Tan, Singapore (SG); Wei Hong Lim, Kuala Lumpur (MY)

(21) Appl. No.: 18/890,691

(22) Filed: Sep. 19, 2024

(51) Int. Cl. H04R 17/02; B81B 3/00; B81C 1/00

(52) U.S. Cl. CPC H04R 17/02; B81B 3/0072; B81C 1/00666; B81B 2201/0257; B81B 2203/0127; B81B 2203/0307; B81B 2203/0376; B81C 2201/0105; B81C 2201/0132; H04R 2201/003

(57) ABSTRACT

Embodiments of the present invention relate to the technical field of semiconductor devices and disclose a MEMS microphone and a method for preparing the same. In the disclosure, the substrate is provided with at least one chamfer at an inner edge of a side of the substrate close to the diaphragm, so that when the diaphragm is bent towards the substrate due to vibration, providing the chamfer can prevent the diaphragm from hitting the substrate, or increase the contact area between the diaphragm and the substrate when the diaphragm hits the substrate, avoiding the concentration of stress and thus reducing the risk of the diaphragm breaking. In this way, the probability of failure of the MEMS microphone due to breakage of the diaphragm can be reduced, and the robustness of the MEMS microphone can be enhanced.

### TECHNICAL FIELD

The various embodiments described in this document relate in general to the technical field of semiconductor devices, and more specifically to a MEMS microphone and a method for preparing the MEMS microphone.

### BACKGROUND

Micro-electro-mechanical system (MEMS) is a micro sensor or actuator made on the basis of semiconductor materials by using micro-electronics technology and micro-machining technology. The MEMS microphone is one of the micromotor systems. Compared with the traditional electret capacitive microphone, the MEMS microphone has better acoustic performance, higher signal-to-noise ratio, better consistent sensitivity, and lower power consumption. The MEMS microphones have been widely used in smartphones, laptops, and other fields for providing better voice quality.

The MEMS microphone includes a back plate and a diaphragm that are opposite to each other, and the back plate and the diaphragm form a variable capacitor. A movable structure of the MEMS microphone, such as the diaphragm, is bent with the change of the air pressure when the sound wave causes change of the air pressure, so that a capacitance value of the variable capacitor changes. The existing MEMS microphones are prone to failure due to structural damage caused by the structural design defects, resulting in weak robustness of the MEMS microphone.

Therefore, a solution capable of enhancing the robustness of the MEMS microphone needs to be provided.

### SUMMARY

Embodiments of the disclosure aim to provide a MEMS microphone and a method for preparing the MEMS microphone, which can overcome the problem of weak robustness of the existing MEMS microphone.

In order to solve the above technical problems, according to a first aspect, an embodiment of the present disclosure provides a MEMS microphone. The MEMS microphone includes a substrate, defining a cavity; at least one anchoring member disposed on the substrate; and a diaphragm having at least one beam structure, where each of the at least one beam structure is fixed on a respective anchoring member of the at least one anchoring member, and the diaphragm covers the cavity and is spaced apart from the substrate. The substrate is provided with at least one chamfer at an inner edge of a side of the substrate close to the diaphragm

In some embodiments, the substrate is provided with a plurality of step portions in a direction from the diaphragm toward the substrate, and at least an inner edge of a step portion of the plurality of step portions closest to the diaphragm is provided with a chamfer.

In some embodiments, heights of the plurality of step portions gradually increase in the direction from the diaphragm toward the substrate.

In some embodiments, an inner edge of each of the plurality of step portions is provided with a chamfer.

In some embodiments, a respective chamfer of the at least one chamfer is a rounded chamfer.

In some embodiments, the rounded chamfer has a radian of R, wherein 0<R≤π/2.

In some embodiments, the rounded chamfer has a radian of R, wherein π/6≤R≤π/2.

In some embodiments, the rounded chamfer has a radian of R, wherein π/4≤R≤π/2.

In some embodiments, a respective chamfer of the at least one chamfer is an oblique chamfer.

According to a second aspect, an embodiment of the present disclosure provides a method for preparing the MEMS microphone. The method includes the following. A substrate is provided, where the substrate includes a first region and a second region surrounding the first region. The first region of the substrate is etched to form a groove and an inner edge of an opening of the substrate close to the groove is etched to form at least one chamfer. The at least one anchoring member is formed on the substrate. The diaphragm having the at least one beam structure is formed over the substrate, where each of the at least one beam structure is fixed on the respective anchoring member of the at least one anchoring member. A cavity is formed by etching a region of the substrate corresponding to the groove to penetrate the substrate, such that the diaphragm covers the cavity and is spaced apart from the substrate.

### BRIEF DESCRIPTION OF THE DRAWINGS

One or more embodiments are exemplary illustrated by the pictures in the accompanying drawings, which do not constitute a limitation to the embodiments, elements having the same reference numeral signs in the accompanying drawings are represented as similar elements, and the drawings in the drawings do not constitute a scale limitation unless otherwise stated.

FIG. 1 is a top view of a partial structure of a MEMS microphone according to a first embodiment of the present disclosure.

FIG. 2 is a schematic cross-sectional view of the MEMS microphone of FIG. 1 along line AA′.

FIG. 3 is an enlarged schematic view of region A of FIG. 2.

FIG. 4 is a schematic diagram of the stress distribution at a contact edge of the diaphragm when a sharp edge is provided.

FIG. 5 is a schematic diagram of the stress distribution at the contact edge of the diaphragm when the step portion having an extension width of 5 μm and a chamfer at the edge of the step portion.

FIG. 6 is a schematic diagram of the stress distribution at the contact edge of the diaphragm when the step portion having an extension width of 7 μm and a chamfer at the edge of the step portion.

FIG. 7 is a schematic diagram of the stress distribution at the contact edge of the diaphragm when the step portion having an extension width of 8 μm and a chamfer at the edge of the step portion.

FIG. 8 is a schematic diagram of the stress distribution at the contact edge of the diaphragm when the step portion having an extension width of 10 μm and a chamfer at the edge of the step portion.

FIG. 9 is a flow chart of a method for preparing the MEMS microphone provided in the present disclosure.

FIG. 10A is a schematic diagram of a structure in which a groove is defined on a substrate.

FIG. 10B is a schematic diagram of a structure in which a first sacrificial layer is filled in the groove.

FIG. 10C is a schematic diagram of a structure after the first sacrificial layer is subjected to flattening treatment.

FIG. 10D is a schematic diagram of a structure in which a second sacrificial layer is formed over the substrate.

FIG. 10E is a schematic diagram of a structure in which a diaphragm is provided on the second sacrificial layer.

FIG. 10F is a schematic diagram of a structure in which a third sacrificial layer is provided on the diaphragm.

FIG. 10G is a schematic diagram of a structure in which a back plate is provided on the third sacrificial layer.

FIG. 10H is a schematic structural diagram of a MEMS microphone formed after etching the substrate and sacrificial layers.

### DETAILED DESCRIPTION OF THE EMBODIMENTS

In order to enable the object, technical solutions, and advantages of the embodiments of the disclosure clearer, embodiments of the disclosure may be described in detail below with reference to accompanying drawings. However, one of ordinary skill in the art may appreciate that in various embodiments of the disclosure, numerous technical details have been provided to better understand the application for the reader. It can be understood that even without these technical details and variations and modifications based on the following embodiments, the technical solutions herein may be realized.

In embodiments of the disclosure, terms “up”, “down”, “left”, “right”, “front”, “back”, “top”, “bottom”, “inside”, “outside”, “middle”, “vertical”, “horizontal”, “transverse”, “longitudinal”, and the like indicating an orientation or positional relationship are orientation or positional relationship based on the drawings. These terms are mainly intended to better describe the disclosure and embodiments of the disclosure and are not intended to limit that the indicated device, element, or component must have a particular orientation or be constructed and operated in the particular orientation.

In addition, some of the above terms may be used to express other meanings besides the orientation or positional relationship. For example, the term “up” may also be used to express a certain attachment or connection relationship in some cases. The specific meanings of these terms in the disclosure may be understood by those of ordinary skill in the art according to actual situations.

Furthermore, terms “installation”, “set-up”, “providing”, “definition”, “connection”, and “coupling” should be understood broadly. For example, the “connection” and “coupling” can be understood as a fixed connection, a detachable connection, or a monolithic construction. Alternatively, the “connection” and “coupling” can be understood as a mechanical connection or an electrical connection, or a direct connection, or indirect connection through an intermediate medium. Alternatively, the “connection” and “coupling” may indicate internal connection between two devices, elements, or components. The specific meanings of the above terms in the disclosure may be understood by those of ordinary skill in the art according to actual situations.

Furthermore, terms “first”, “second”, etc. are mainly used to distinguish from different devices, elements, or components (specific types and configurations of the devices, elements, or components may be the same or different), and are not intended to indicate or imply the relative importance and quantity of the indicated devices, elements, or components. Unless otherwise stated, “multiple/a plurality of”means two or more.

In some MEMS microphones, the diaphragm generally has at least one beam structure and is fixed on at least one anchoring member through the at least one beam structure, so as to cover the cavity of the substrate in the MEMS microphone. A back plate is disposed on the diaphragm, and there is a gap between the diaphragm and the back plate, and thus the diaphragm and the back plate form a variable capacitor. During operating of the MEMS microphone, the diaphragm vibrates due to the influence of sound pressure, and is bent when vibrating, such that the capacitance value of the variable capacitor is changed. However, since there is no support between the at least one beam structure and the substrate, during the vibration of the diaphragm, the at least one beam structure not only acts as the stress concentration point of bending deformation, but also bears the force due to repeatedly hitting the edge of the substrate, so that the diaphragm is easily damaged. Generally, the stress at the contact point between the diaphragm and the substrate can be reduced by increasing the width of the at least one beam structure, but this may lead to a decrease in the sensitivity of the device. Alternatively, the edge of the substrate can be provided closer to the at least one anchoring member to reduce the stress at the contact point, but this may cause the stress on the at least one anchoring member, thus increasing the risk of failure of the device.

The disclosure aims to reduce the stress between the diaphragm and the edge of the substrate without changing the configuration of the diaphragm and without adding other additional structures, thereby reducing the risk of damage of the diaphragm, such that the MEMS microphone can have good robustness.

Embodiments of the present disclosure provide a MEMS microphone, and the MEMS microphone includes: a substrate defining a cavity; at least one anchoring member disposed on the substrate; and a diaphragm having at least one beam structure, where each of the at least one beam structure is fixed on a respective anchoring member of the at least one anchoring member, so that the diaphragm covers the cavity and is spaced apart from the substrate. The substrate is provided with at least one chamfer at an inner edge of a side of the substrate close to the diaphragm.

Embodiments of the disclosure further provide a method for preparing the MEMS microphone, including: providing a substrate including a first region and a second region surrounding the first region; etching the first region to form a groove, etching an inner edge of an opening of the groove to form at least one chamfer; filling a sacrificial layer in the groove and performing a flattening treatment on the sacrificial layer; forming a diaphragm on the sacrificial layer; and etching a region of the substrate corresponding to the groove to form a cavity.

In this embodiment, the substrate is provided with at least one chamfer at an inner edge of a side of the substrate close to the diaphragm. When the diaphragm is bent towards the side of the substrate due to vibration, proving the at least one chamfer can prevent the diaphragm from hitting the substrate, or increase a contact area between the diaphragm and the substrate when the diaphragm hits the substrate, so as to avoid stress concentration, thereby reducing the risk of damage of the diaphragm. In this way, the probability of failure of the MEMS microphone due to damage of the diaphragm can be reduced, and the robustness of the MEMS microphone can be enhanced.

The implementation details of the MEMS microphone of the present embodiment will be described in detail below. The following contents are provided implementation details only for the convenience of understanding the disclosure, and are not necessary for implementing the present scheme.

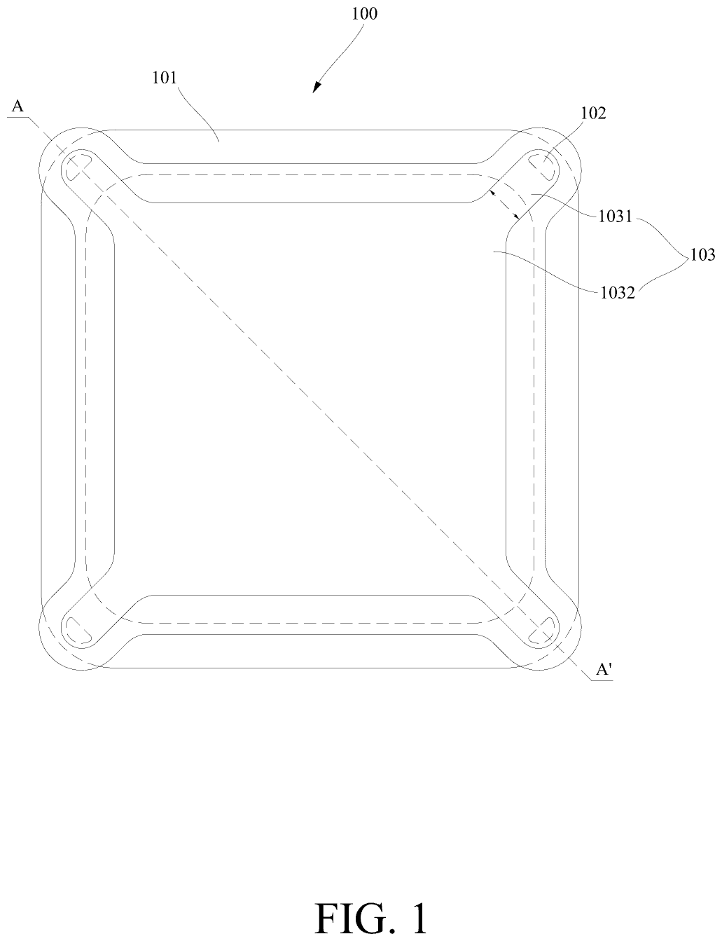

Referring to FIGS. 1 to 3, the substrate 101 of the MEMS microphone 100 of the present embodiment is provided to have an annular shape, such as a square annular shape or a circular annular shape. The substrate 101 defines a cavity 1011, and the cavity 1011 penetrates the substrate 101, thereby forming a vibration space for the MEMS microphone 100. In some embodiments, the substrate 101 may be a monocrystalline silicon substrate or other substrates satisfying design requirements.

The at least one anchoring member 102 is disposed on the substrate 101. For example, there are a plurality of anchoring members 102 on a surface of the substrate 101, and the plurality of anchoring members 102 are provided around the axis of the substrate 101 and spaced apart from each other. The at least one anchoring member 102 may be made of silicon nitride or silicon dioxide.

The diaphragm 103 has at least one beam structure 1031 and a vibrating portion 1032. The at least one beam structure 1031 and the vibrating portion 1032 may be integrally formed. The number of the at least one beam structure 1031 may be the same as the number of the at least one anchoring member 102, and each of the at least one beam structure 1031 of the diaphragm 103 is fixed to a respective one of the at least one anchoring member 102, so that the vibrating portion 1032 is disposed over the cavity 1011. There is a spacing between the diaphragm 103 and the substrate 101.

Generally, when the diaphragm 103 is bent due to vibration, the at least one beam structure 1031 is subjected to stress and may collide with the edge 1012 of the substrate 101. Since an edge of the conventional substrate is a right-angled edge, the beam structure 1031 is easily subjected to stress concentration during collision, thus resulting in damage to the diaphragm 103. In the present disclosure, the edge 1012 is set to have a chamfer, which increases a distance between the beam structure 1031 and the edge 1012. When the diaphragm 103 is bent, the beam structure 1031 may not easily collide with the edge 1012. Even if the beam structure 1031 collides with the edge 1012, since the edge 1012 is set to have the chamfer, a contact area between the beam structure 1031 and the edge 1012 is increased, the stress generated by the collision can be effectively dispersed, the risk of damage to the beam structure 1031 can be reduced, and the robustness of the MEMS microphone 100 can be enhanced.

In some embodiments, there are a plurality of step portions 1013 on an inner wall of the substrate 101 in a direction from the diaphragm 103 toward the substrate 101 (in a direction perpendicular to the surface of the substrate). In some embodiments, at least an edge 1012 of a step portion 1013 of the plurality of step portions 1013 closest to the diaphragm 103 is provided with a chamfer. By providing the plurality of step portions 1013, the contact points between the beam structure 1031 and the substrate 101 can be increased, the stress generated when the beam structure 1031 collides with the substrate 101 can be further dispersed, the stress concentration can be avoided, and the MEMS microphone 100 has good robustness.

It is to be noted that widths of the plurality of step portions 1013 gradually increase in the direction from an edge of the diaphragm 103 to a central position of the diaphragm 103 (for example, if the substrate is a circular annular substrate, the direction from the edge of the diaphragm 103 to the central position of the diaphragm 103 refers to a radial direction of the circular annular substrate). In other words, if a step portion 1013 is further away from the diaphragm 103, an edge of the step portion 1013 is closer to a central position of the vibrating portion 1032, and there is a greater spacing between the step portion 1013 and the diaphragm 103. For example, if there are at least two step portions 1013 including a first step portion and a second step portion, a minimum distance between the second step portion and the diaphragm 103 is larger than a minimum distance between the first step portion and the diaphragm 103, an edge of the second step portion is closer to a central position of the vibrating portion 1032 than that of the first step portion.

In some embodiments, heights of the plurality of step portions 1013 gradually increase in the direction from the diaphragm 103 toward the substrate 101. During vibrating of the diaphragm 103, the central position of the vibrating portion 1032 is subjected to largest sound pressure, and thus, an amplitude of bending deformation at the central position of the vibrating portion 1032 is also the largest. From the central position to an edge position of the vibrating portion 1032, the effect of the sound pressure on the diaphragm 103 gradually decreases, and the amplitude of the bending deformation is also gradually reduced. Especially at the position with the beam structure 1031, the amplitude of the bending deformation of the diaphragm 103 is smallest due to the effect of the beam structure 1031. Therefore, a step portion 1013 closer to the diaphragm 103 is provided to have a small height, and a step portion 1013 further away from the diaphragm 103 is provided to have a large height. Therefore, when the diaphragm 103 is subjected to the sound pressure, the diaphragm 103 can be ensured to concurrently land on each of the plurality of step portions 1013, so as to disperse the stress applied to the diaphragm 103. The effect of the above arrangement is particularly significant when the pressure exerted on the diaphragm 103 increases.

In some embodiments, the widths of the plurality of step portions 1013 in the direction from the edge of the diaphragm 103 to the central position of the diaphragm 103 are also configured, to enable the diaphragm 103 to concurrently land on each step portion 1013 when the pressure on the diaphragm 103 increases.

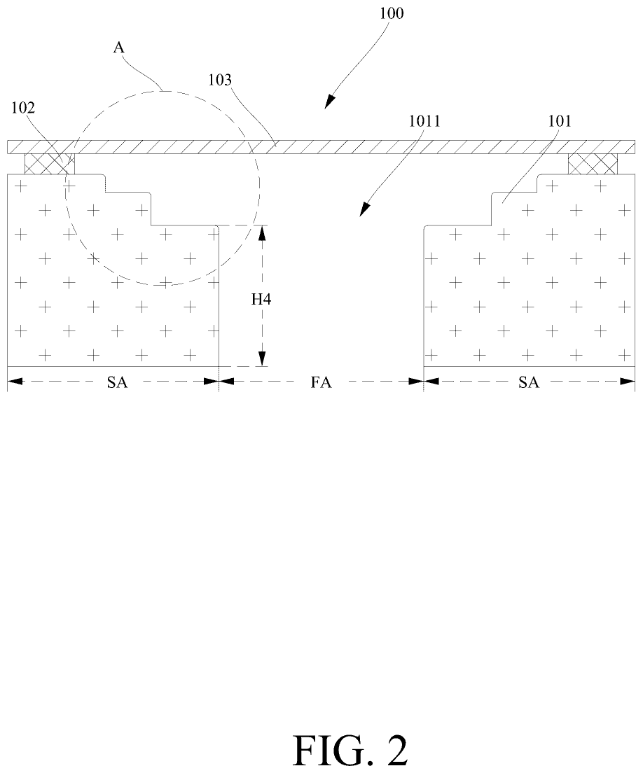

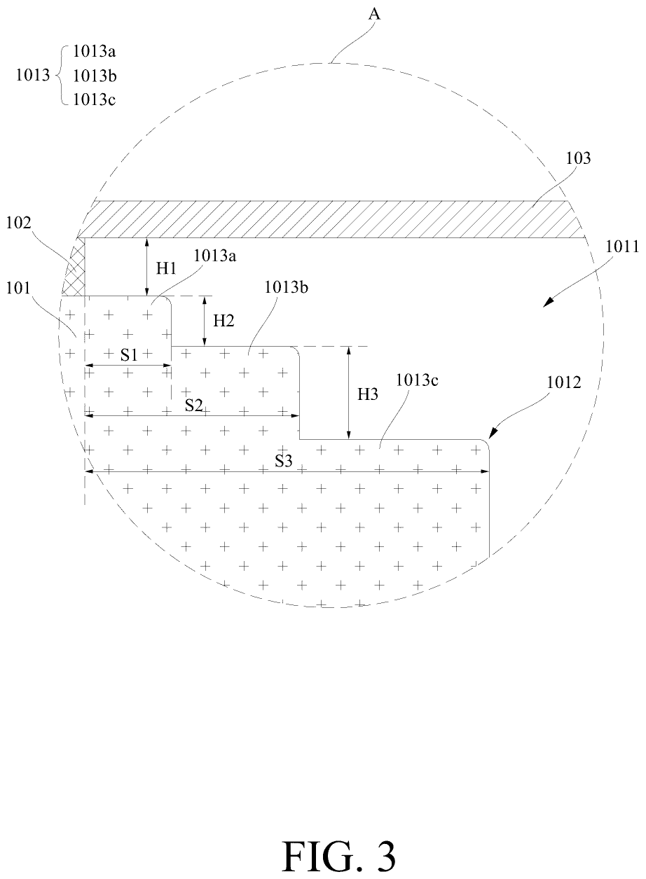

Referring again to FIGS. 2 and 3, the following describes three step portions 1013 as an example of the number of step portions 1013. The step portions arranged in sequence in the direction perpendicular to the surface of the substrate include a first step portion 1013a, a second step portion 1013b, and a third step portion 1013c. A spacing between the first step portion 1013a and the diaphragm 103 may be equal to a height H1 of the anchoring member 102. If a height of the first step portion 1013a is H2, a spacing between the second step portion 1013b and the diaphragm 103 is equal to H1+H2. If a height of the second step portion 1013b is H3, a spacing between the third step portion 1013c and the diaphragm 103 is equal to H1+H2+H3. A height of the third step portion 1013c is represented as H4, where H2<H3<H4.

In the direction from the edge of the diaphragm 103 to the central position of the diaphragm 103, a width of a portion of the first step portion 1013a exceeding the anchoring member 102 is represented as S1 (i.e., S1 refers to a distance between an edge of the anchoring member 102 facing the central position of the diaphragm 103 and an edge of the first step portion 1013a facing the central position of the diaphragm 103), a width of a portion of the second step portion 1013b exceeding the anchoring member 102 is represented as S2, and a width of a portion of the third step portion 1013c exceeding the anchoring member 102 is represented as S3, where S1□S2□S3. A difference value between S2 and S1 is represented as ΔS1 and a difference value between S3 and S2 is represented as ΔS2, where ΔS1<ΔS2, or ΔS1=ΔS2, or ΔS1>ΔS2.

It shall be understood that there is no restriction on the specific number of step portions 1013, the specific heights of different step portions 1013, the specific widths of different step portions 1013, and the height difference and the width difference between the different step portions 1013, which can be specifically set according to different MEMS microphones, and will not be described in detail here.

In addition, there may be provided with a plurality of step portions 1013 for each of the at least one beam structure 1031.

In some embodiments, in view of saving processing steps and reducing manufacturing difficulty, the edge of the step portion 1013 furthest away from the diaphragm 103 may not be set to have a chamfer, but rather maintained at a right angle. Taking the third step portion 1013c as an example, in this case, the edge of the third step portion 1013c is relatively sharp relative to the diaphragm 103. In order to prevent the diaphragm 103 from being damaged due to being deeply trapped into the edge of the third step portion 1013c caused by excessive pressure, it is necessary to set a value of H3/ΔS2 to be relatively large. In this way, when the diaphragm 103 is bent and deformed towards the substrate 101 after being subjected to a greater pressure, the edge of the second step portion 1013b can well block the diaphragm 103, and reduce the extent of the continued deformation of the diaphragm 103, so as to prevent the diaphragm 103 from hitting the edge of the third step portion 1013c. In this case, since the first step portion 1013a and the second step portion 1013b well block and reduce the deformation amplitude of the diaphragm 103, so that the diaphragm 103 may not hit the edge of the third step portion 1013c. Therefore, the specific position of the edge of the third step portion 1013c does not significantly affect the device within a certain range when manufacturing the third step portion 1013c. In particular, there are generally errors in the actual manufacturing process. In the above design, regardless of whether the edge position of the third step portion 1013c exceeds or is less than a predetermined position within a certain range, such as ±10 μm, the effectiveness of the device may not be affected.

In other embodiments, the edge of each step portion 1013 are provided to have a chamfer. In this way, the robustness of the MEMS microphone 100 can be further enhanced.

Alternatively, the chamfer provided at the edge of the step portion 1013 is an oblique chamfer or a rounded chamfer. In the disclosure, the chamfer is set as a rounded chamfer. Compared with the oblique chamfer, with aid of the rounded chamfer, the contact area between the diaphragm 103 and the substrate 101 can be increased when the diaphragm 103 hits the substrate 101, the stress concentration of the diaphragm 103 can be further avoided due to no sharp edges in the rounded chamfer. In addition, both the oblique chamfer and the rounded chamfer are provided in the MEMS microphone, that is, the edge of each of some step portions 1013 is provided to have an oblique chamfer, and the edge of each of other step portions 1013 is provided to have a rounded chamfer.

In some embodiments, a radian of the rounded chamfer is represented as R, where 0<R≤π/2. When the radian of the rounded chamfer is π/2, an end face of the step portion 1013 facing the cavity 1011 is perpendicular to an extension plane of the diaphragm 103. In this case, the rounded chamfer is relatively easy to form, which facilitates the machining. When the radian of the rounded chamfer is less than π/2, for example, R=π/12 or R=π/6, the end surface of the step portion 1013 facing the cavity 1011 is an inclined surface. Compared with the case where the radian of the rounded chamfer is π/2, this design in which the radian of the rounded chamfer is less than π/2 can further increase the contact area between the diaphragm 103 when deformed and the substrate 101. For the step portion 1013 having a specific height, when the radian of the rounded chamfer is relatively small, a length of the inclined surface is relatively long, so that a width of the step portion 1013 is relatively large. Therefore, the radian of the rounded chamfer can be set to be π/4 or π/3 (R=π/4 or R=π/3). In this case, the contact area between the diaphragm 103 when deformed and the substrate 101 can be increased, and the width of the step portion 1013 can be effectively limited.

It is to be noted that when the radian of the rounded chamfer is in a range of 0<R≤π/6, the contact area between the diaphragm 103 when deformed and the substrate 101 can be greatly increased at the edge of the step portion 1013. When the radian of the rounded chamfer is in a range of π/6□R≤π/3, the width of the step portion 1013 can be effectively controlled, and the contact area between the diaphragm 103 when the diaphragm 103 is deformed and the substrate 101 can be increased. When the radian of the rounded chamfer is in a range of π/3□R≤π/2, the width of the step portion 1013 can be well controlled. Especially when the radian of the rounded chamfer is π/2 (R=π/2), the machining difficulty of the rounded chamfer can be well reduced.

It is to be noted that different step portions 1013 may have rounded chamfers of different radians or a same radian, which may be set according to the actual requirements of the device, and are not described herein.

When the edge of the step portion 1013 is set to have an oblique chamfer, an angle formed between an inclined surface forming the oblique chamfer and a top surface of the step portion 1013 facing the diaphragm 103 may also be set according to the actual situation, for example, may be set to 120 degree (120°), 135°, 150°, or other degrees, which will not be described here in detail.

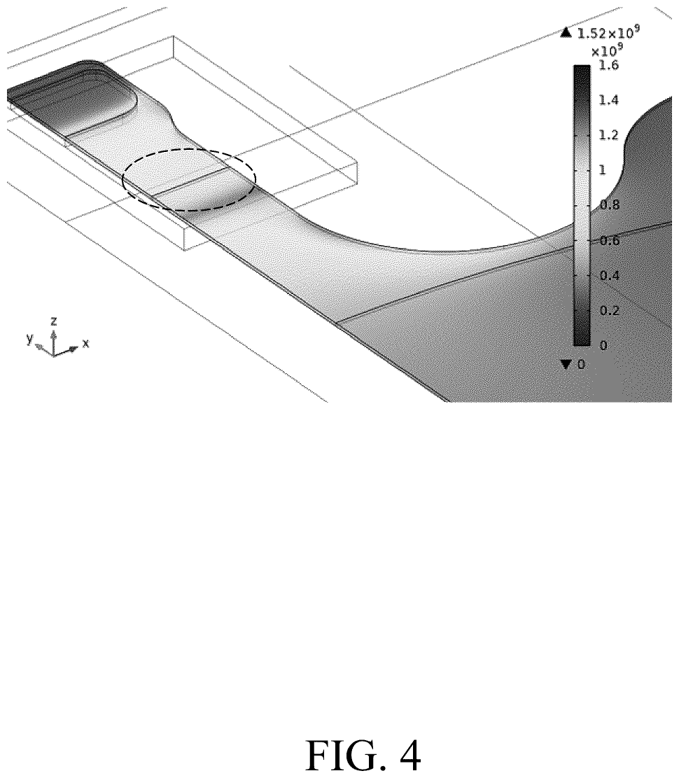

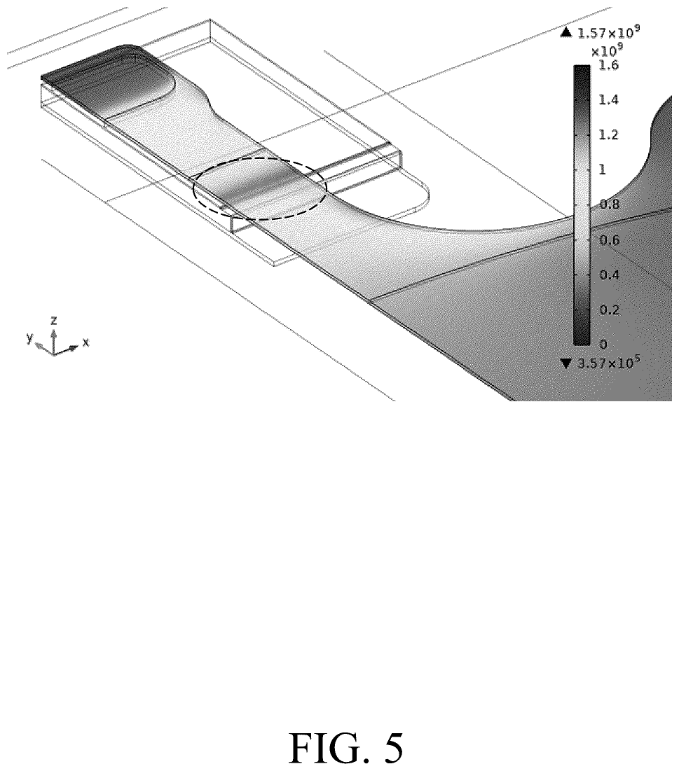

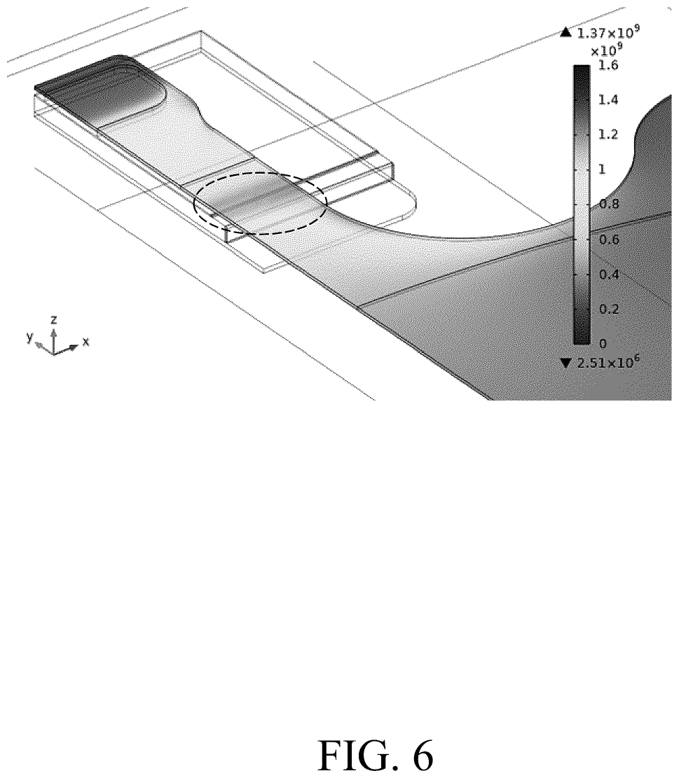

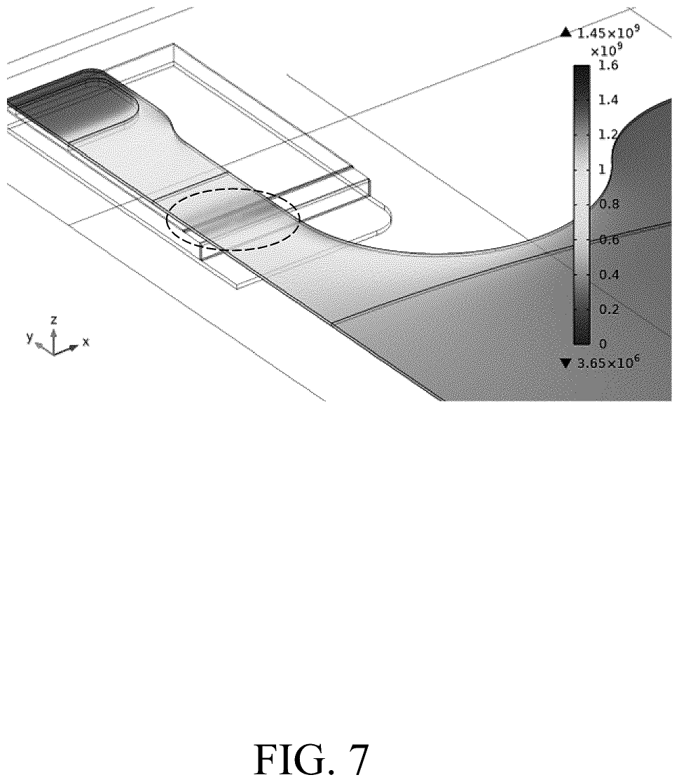

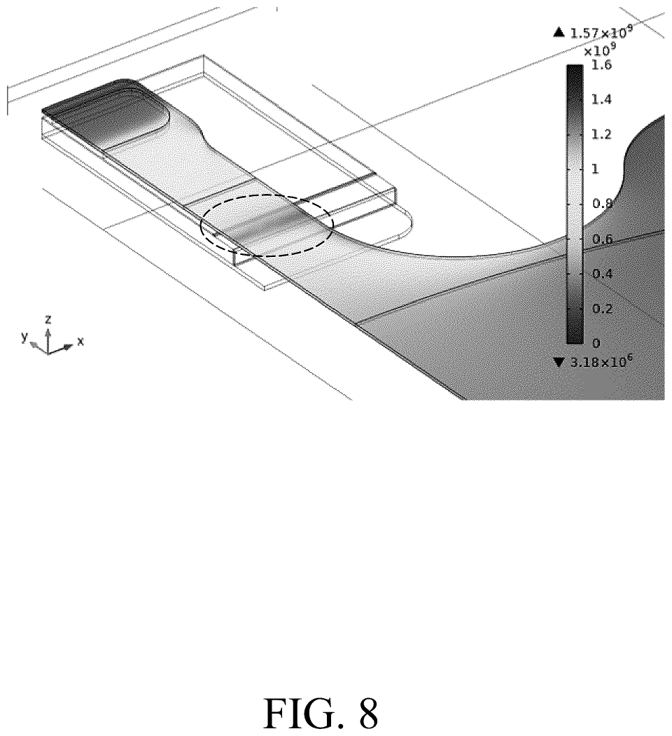

FIGS. 4 to 8 illustrate a magnitude of the stress at the contact point of the beam structure 1031 and the step portion 1013 when different numbers of step portions 1013 are provided at a pressure of 50 kPa, and a magnitude of the stress at the contact point of the beam structure 1031 and the step portion 1013 when a difference between widths of two step portions 1013 varies. FIG. 4 is a schematic diagram illustrating stress of a contact point between the beam structure 1031 and the step portion 1013 when a step portion 1013 is provided and no chamfer is provided (in this case, the edge of the step portion has sharp corner). FIG. 5 is a schematic diagram of the stress at the contact point of the beam structure 1031 and the step portions 1013 when two step portions 1013 with chamfers are provided (in this case, the inner edge of each of the two edge portions has a round corner) and a width difference between the two step portions 1013 is 5 μm. FIG. 6 is a schematic diagram of the stress at the contact point of the beam structure 1031 and the step portions 1013 when two step portions 1013 with chamfers are provided and a width difference between the two step portions 1013 is 7 μm. FIG. 7 is a schematic diagram of the stress at the contact point of the beam structure 1031 and the step portions 1013 when two step portions 1013 with chamfers are provided and a width difference between the two step portions 1013 is 8 μm. FIG. 8 is a schematic diagram of the stress at the contact point of the beam structure 1031 and the step portions 1013 when two step portions 1013 with chamfers are provided and a width difference between the two step portions 1013 is 10 μm.

In embodiments of the disclosure, when two step portions 1013 are provided and the width difference between the two step portions 1013 is 5 μm, since the width of the second step portion exceeds the width of the first step portion by a small amount (i.e., the second step portion is just slightly larger than the first step portion), the two step portions 1013 may not effectively support the deformed diaphragm 103, and therefore, the stress at the contact point between the diaphragm 103 and the substrate 101 is still relatively large. When the width difference between the two step portions 1013 is 7 μm, both step portions 1013 can effectively support the deformed diaphragm 103, so that the stress at the contact point between the diaphragm 103 and the substrate 101 is reduced by about 10%, i.e., the stress at the contact point is significantly reduced. When the width difference between the two step portions 1013 is 8 μm, the width difference between the two step portions 1013 is further increased, and support of the second step portion after the deformation of the diaphragm 103 is more significant. Therefore, the maximum stress at the stress concentration point is increased compared with the solution where the width difference is 7 μm. When the width difference between the two step portions 1013 is 10 μm, the diaphragm 103 after deformed is mainly supported by the second step portion, and the support effect of the first step portion is significantly reduced, so that the maximum stress at the stress concentration point is roughly the same as that of the solution where there is only one step portion 1013.

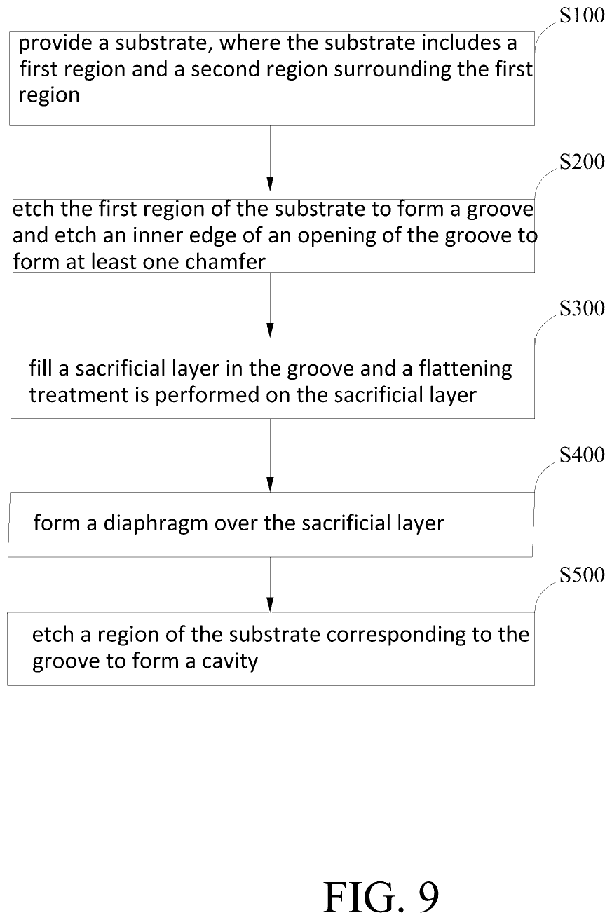

Referring to FIG. 9, a second embodiment of the present disclosure provides a method for preparing the MEMS microphone 100 described above. The method includes the following.

At S100, a substrate is provided, where the substrate includes a first region and a second region surrounding the first region.

At S200, the first region of the substrate is etched to form a groove, and an inner edge of an opening of the groove is etched to form at least one chamfer.

At S300, a sacrificial layer is filled in the groove and a flattening treatment is performed on the sacrificial layer.

At S400, a diaphragm is formed on the sacrificial layer.

At S500, a region of the substrate corresponding to the groove is etched to form a cavity. That is, continue to etch the first region of the substrate to penetrate the substrate.

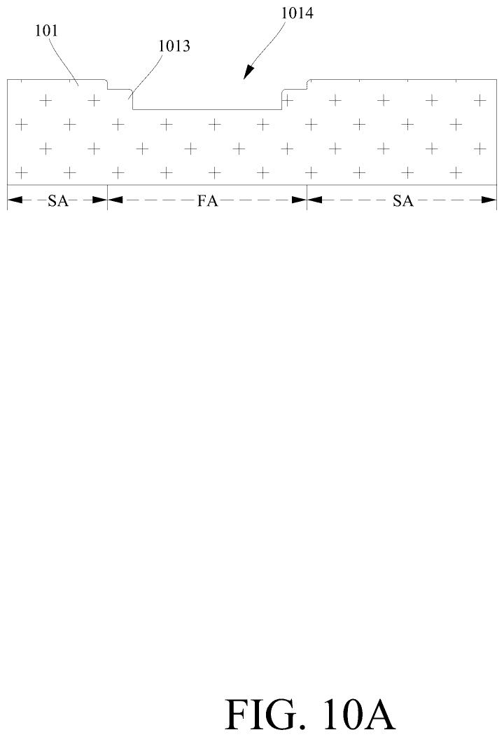

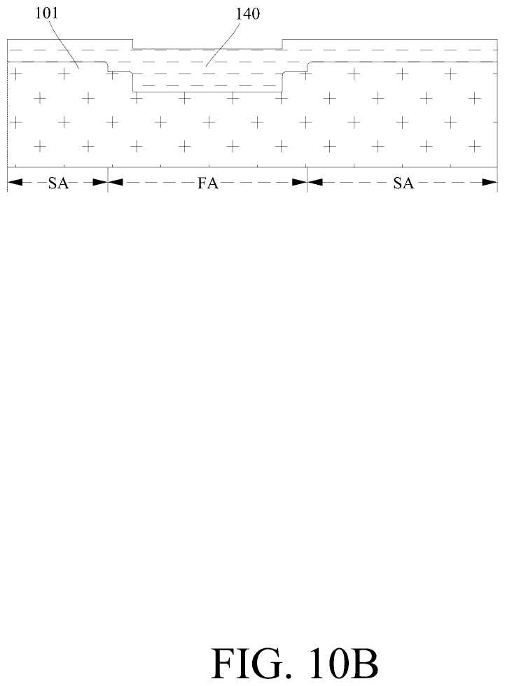

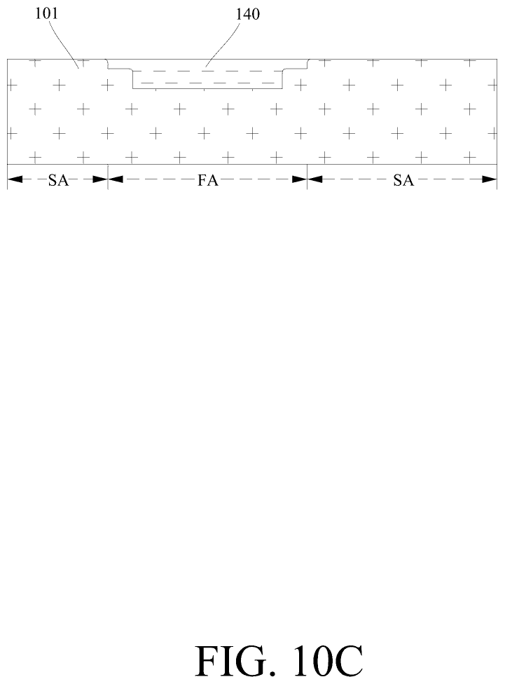

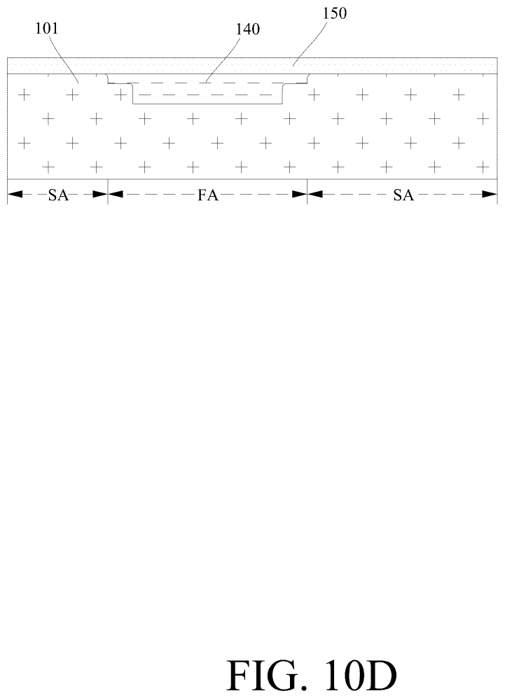

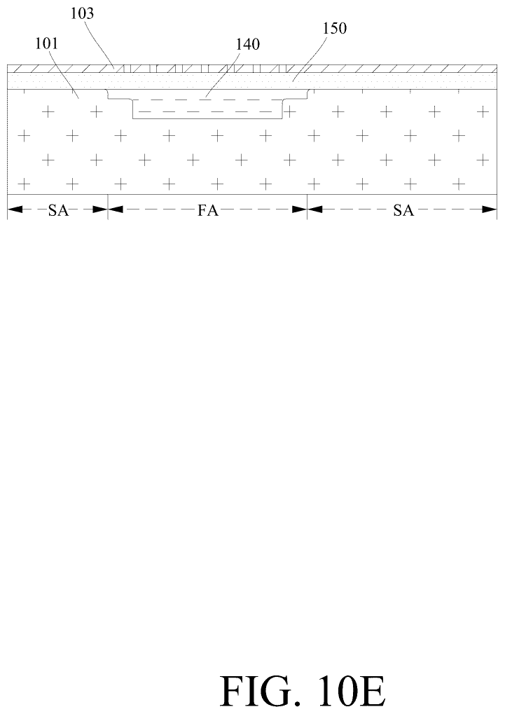

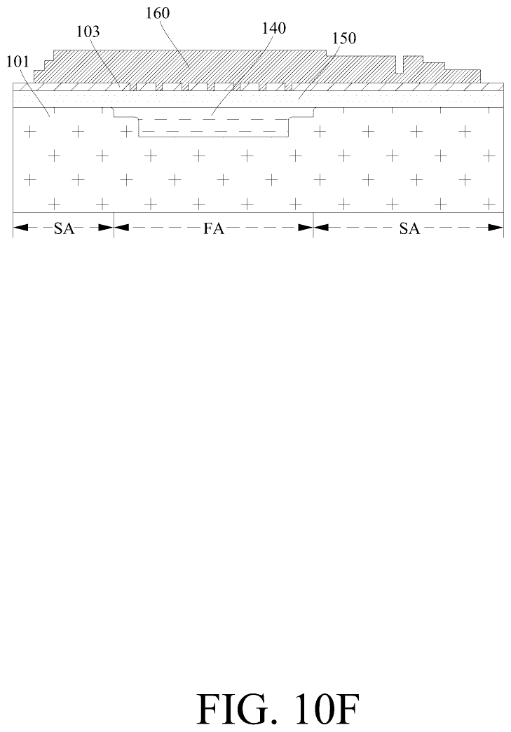

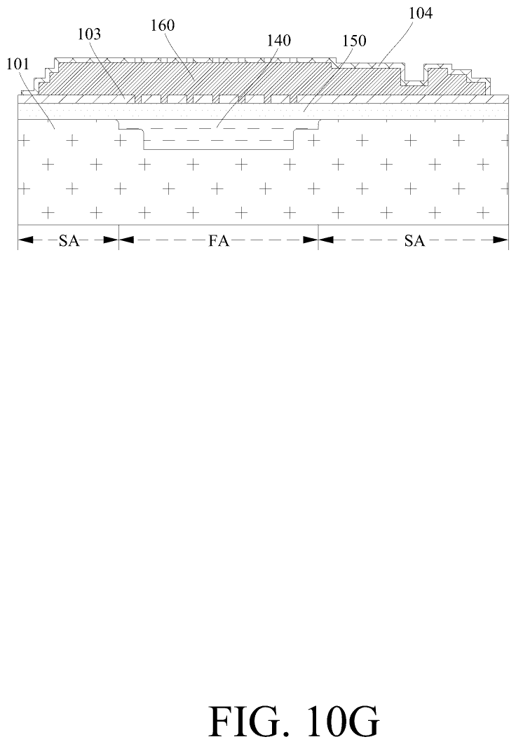

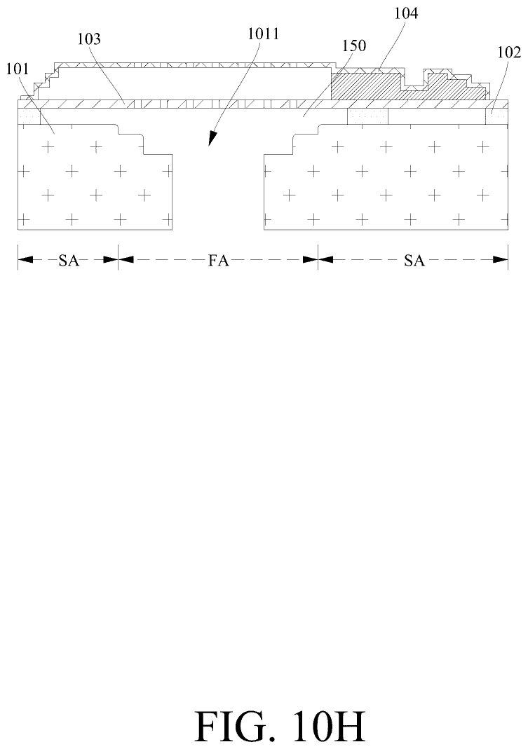

Referring to FIGS. 10A to 10H, at S100, a substrate 101 is provided, where the substrate 101 includes a first region FA and a second region SA surrounding the first region FA. Specifically, the substrate 101 is divided into the first region FA and the second region SA according to actual needs, the second region SA is arranged around the first region FA, and the first region FA corresponds to the cavity 1011 formed subsequently.

At S200, the groove 1014 is formed by etching the first region FA of the substrate 101, and an inner edge of an opening of the groove 1014 is etched to form at least one chamfer. Specifically, the groove 1014 is formed by etching the first region FA using an etching method such as photolithography, and the at least one chamfer, such as an oblique chamfer or a rounded chamfer, is formed at the edge of the groove 1014 by a global dry etching.

Furthermore, more grooves may be further formed by etching the bottom of the groove 1014 as needed, and a bottom area of the opening of each of the grooves subsequently etched is smaller than a bottom area of the groove 1014, thereby forming a stepped groove. That is, there are a plurality of step portions 1013 formed on an inner wall of the substrate 101. After the stepped groove is formed, at least one rounded chamfer or oblique chamfer may be formed by etching at the edge of each step portion 1013 of the stepped groove by the global dry etching.

At S300, the first sacrificial layer 140 is filled in the groove, and the first sacrificial layer 140 is subjected to flattening treatment. Specifically, the stepped groove is filled with silicon dioxide or other usable materials, and after the first sacrificial layer 140 is cured, a portion of the first sacrificial layer 140 extending beyond an upper surface of the substrate 101 is removed, so that the first sacrificial layer 140 is substantially flush with the upper surface of the substrate 101.

At S400, the diaphragm 103 is formed over the sacrificial layer. Specifically, a second sacrificial layer 150 is formed on the first sacrificial layer 140, and the diaphragm 103 is formed on the second sacrificial layer 150 after the second sacrificial layer 150 is cured.

At S500, a region of the substrate 101 corresponding to the groove 1014 is etched to form a cavity 1011. Specifically, the cavity 1011 penetrating the substrate 101 is formed by etching from the bottom surface of the substrate 101, and the first sacrificial layer 140 and part of the second sacrificial layer 150 are removed, where another part of the second sacrificial layer 150 located outside the first region FA is used as at least one anchoring member 102 to fix the diaphragm 103. That is, the at least one anchoring member is formed on the second region of the substrate, and a respective one of at least one beam structure of a diaphragm is fixed on a respective anchoring member of the at least one anchoring member to fix the diaphragm.

It shall be understood that after forming the diaphragm 103 and before forming the cavity 1011, the method for preparing the MEMS microphone 100 further includes the following.

At S600, a third sacrificial layer 160 is provided on the diaphragm 103, and a back plate 104 is formed on the third sacrificial layer 160. Specifically, a plurality of through holes are formed by etching the diaphragm 103, the plurality of through holes are filled with the third sacrificial layer 160 to cover the diaphragm 103, and a flattening treatment is performed on a surface of the third sacrificial layer 160. Thereafter, a back plate 104 of the MEMS microphone 100 is formed on the third sacrificial layer 160, and a plurality of through holes are defined on the back plate 104 by etching. Finally, part of the substrate 101, all of the first sacrificial layer, part of the second sacrificial layer 150, and part of the third sacrificial layer 160 are removed by etching from the bottom surface of the substrate 101.

The MEMS microphone provided in the embodiments of the present disclosure and the preparation method thereof are described in detail above. The principle and the embodiment of the present disclosure are described herein through specific examples. The illustration of the above embodiment is only used to help understand the concept of the present disclosure, and there will be changes in the specific embodiment and the application scope. In summary, the content of the present specification should not be understood as a limitation of the present disclosure.

What is claimed is:

1. A MEMS microphone, comprising:
a substrate, defining a cavity;
at least one anchoring member, disposed on the substrate; and
a diaphragm having at least one beam structure, wherein each of the at least one beam structure is fixed on a respective anchoring member of the at least one anchoring member, and the diaphragm covers the cavity and is spaced apart from the substrate;
wherein the substrate is provided with at least one chamfer at an inner edge of a side of the substrate close to the diaphragm.

2. The MEMS microphone of claim 1, wherein the substrate is provided with a plurality of step portions in a direction from the diaphragm toward the substrate, and at least an inner edge of a step portion of the plurality of step portions closest to the diaphragm is provided with a chamfer.

3. The MEMS microphone of claim 2, wherein heights of the plurality of step portions gradually increase in the direction from the diaphragm toward the substrate.

4. The MEMS microphone of claim 2, wherein each step portion of the plurality of step portions is provided with a chamfer at an inner edge of the step portion.

5. The MEMS microphone of claim 1, wherein a respective chamfer of the at least one chamfer is a rounded chamfer.

6. The MEMS microphone of claim 5, wherein the rounded chamfer has a radian of R, wherein 0<R≤π/2.

7. The MEMS microphone of claim 5, wherein the rounded chamfer has a radian of R, wherein π/6≤R≤π/2.

8. The MEMS microphone of claim 5, wherein the rounded chamfer has a radian of R, wherein π/4≤R≤π/2.

9. The MEMS microphone of claim 1, wherein a respective chamfer of the at least one chamfer is an oblique chamfer.

10. The MEMS microphone of claim 2, wherein widths of the plurality of step portions gradually increase in a direction from an edge of the diaphragm to a central position of the diaphragm.

11. A method for preparing the MEMS microphone of claim 1, comprising:
providing the substrate including a first region and a second region surrounding the first region;
forming the at least one chamfer by etching the first region of the substrate to form a groove and etching an inner edge of the substrate close to the groove;
forming the at least one anchoring member on the substrate;
forming the diaphragm having the at least one beam structure over the substrate, wherein each of the at least one beam structure is fixed on the respective anchoring member of the at least one anchoring member; and
forming a cavity by etching a region of the substrate corresponding to the groove to penetrate the substrate, such that the diaphragm covers the cavity and is spaced apart from the substrate.
